(19) United States
(12) Patent Application Publication
(10) Pub. No.: US 2003/0131458 A1
(43) Pub. Date: Jul. 17, 2003

(54) Apparatus and method for improving throughput in a cluster tool for semiconductor wafer processing

(75) Inventors: Hougong Wang, Pleasanton, CA (US); Gongda Yao, Fremont, CA (US); Zheng Xu, Foster City, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/047,549

(22) Filed: Jan. 15, 2002

(51) Int. Cl. H01L 21/00

(52) U.S. Cl. 29/25.01

(57) ABSTRACT

An apparatus and method for processing semiconductor wafers is provided. The apparatus comprises a first buffer chamber having a first robot and a second buffer chamber having a second robot. At least one load lock is coupled to the first buffer chamber and the second buffer chamber where the first and second robots can access at least one of said load locks. A plurality of process chambers are disposed about the first and second buffer chambers.

### BACKGROUND OF THE DISCLOSURE

1. Field of the Invention

The present invention relates to a multi-chamber semiconductor wafer processing system and, more particularly, an apparatus and method for improving throughput of wafers in a multi-chamber semiconductor wafer processing system.

2. Background of Invention

Semiconductor wafer processing is performed by subjecting a wafer to a multitude of sequential processes. These processes are performed in a plurality of process chambers. A collection of process chambers served by one or more wafer transport robots is known as a multi-chamber semiconductor wafer processing tool or cluster tool.

Previous cluster tools consisted of one or two transfer chambers, that each housed a wafer transport robot. The robot distributed wafers and managed wafer movement through a plurality of processing chambers located proximate the transfer chamber.

The wafers are supplied to the transport robot via one or two load locks. Each load lock holds a cassette containing a plurality of wafers. The wafers are accessed by the robot one at a time and processed by the process chambers in a sequential manner. When processing is complete, the processed wafer is returned to a cassette by the same robot that initially retrieved the wafer from the cassette.

Although the prior art has shown itself to be a dependable tool for processing semiconductor wafers, a number of shortcomings are apparent. One example is the limited number of process chambers that can be serviced by the wafer transport robots. A second shortcoming is the number of load locks that are employed to input fresh wafers into the wafer-processing chambers. The limited number of load locks that are accessed by a single robot can lead to bottlenecks where one or more wafers must wait to be moved by the robot. Therefore, a need exists in the art for a multiple process chamber, semiconductor wafer-processing tool having improved wafer-processing throughput.

### SUMMARY OF INVENTION

The disadvantages heretofore associated with the prior art are overcome by a method and apparatus for improving throughput in a cluster tool for semiconductor wafer processing. The invention provides for an additional number of load lock chambers in communication with both the cluster tool and a factory interface without compromising system footprint. The unique use of additional load locks provides for increased throughput by allowing the cluster tool to implement a dual loop process method.

One embodiment of the invention comprises a cluster tool having at least two robotic transfer mechanisms or wafer transfer robots (hereinafter referred to as the robots) where a plurality of load locks are in communication with the robots and at least one load lock is associated with each of the robots. As such, any of the robots can be used to input a “fresh” wafer from an associated load lock into the cluster tool for processing or used to remove a processed wafer from the tool. Consequently, the throughput of the tool is improved.

In an additional embodiment, each robot is associated with at least two load locks. A plurality of process chambers are disposed about the buffer chamber and a factory interface is coupled in communication with the plurality of load locks. A dual loop process method and a parallel loop process method are employed to utilize the additional load locks to create dynamic throughput cycles for processing wafers. The operation of the cluster tool is controlled by a sequencer to implement the methods.

The dual loop method and the parallel process method employed by the invention utilize the load locks as well as the plurality of process chambers in order to improve wafer throughput without increasing the overall footprint of the tool. The dual loop method comprises an inner process loop and an outer process loop. The inner process loop comprises a series of steps that move a wafer within the boundaries defined by an area serviced from a single wafer transfer location, whereby the wafer enters and leaves the wafer transfer location from a single set of load locks associated with one transfer robot.

By contrast, the outer process loop comprises a series of steps that move a wafer circuitously through at least two wafer transfer locations using at least two transfer robots. The wafer is imported into the first buffer chamber through a first set of load locks by a first wafer transfer robot. The wafer may then be processed by any of the process chambers associated with either of the buffer chambers by transferring the wafer to one of the transfer locations where it is then moved by a second wafer transfer robot. In the outer process loop, after processing, the wafer is moved out of the buffer chamber through a different set of locks than that which the wafer entered.

During the parallel loop processing method, each of the transfer chambers and the associated process chambers operate as individual cluster tools. This method allows for continuous uninterrupted wafer processing provided the number of process steps can be accommodated by the process chambers associated with each of the buffer chambers. By employing the dual loop method and a parallel processing method, process chambers that may have been idle for a period of time are now more fully utilized. The increased utilization of process chambers improves throughput by allowing more wafers to be processed in a given amount of time.

### BRIEF DESCRIPTION OF DRAWINGS

The teachings of the present invention can be readily understood by considering the following detailed description in conjunction with the accompanying drawings, in which:

FIG. 1 depicts a schematic diagram of a dual buffer chamber, multiple process chamber semiconductor wafer processing tool in accordance with the present invention;

FIG. 2 depicts a block diagram of the cluster tool of FIG. 1 illustrating wafer movements using an outer loop method, an inner loop method and a parallel loop method;

FIG. 3 depicts a flow diagram of the outer loop method of moving wafers through the cluster tool of FIG. 1;

FIG. 4 depicts a flow diagram of an inner loop method of moving wafers through the cluster tool of FIG. 1;

FIG. 5 depicts a flow diagram of a parallel loop method of moving wafers through a cluster tool of FIG. 1;

FIG. 6 depicts a schematic diagram of a dual buffer chamber, multiple process chamber semiconductor wafer processing tool (6-chambers) in accordance with another embodiment of the present invention; and

FIG. 7 depicts a schematic diagram of a dual buffer chamber, multiple process chamber semiconductor wafer processing tool (10-chambers) in accordance with another embodiment of the present invention.

To facilitate understanding, identical reference numerals have been used, where possible, to designate identical elements that are common to the figures.

### DETAILED DESCRIPTION OF INVENTION

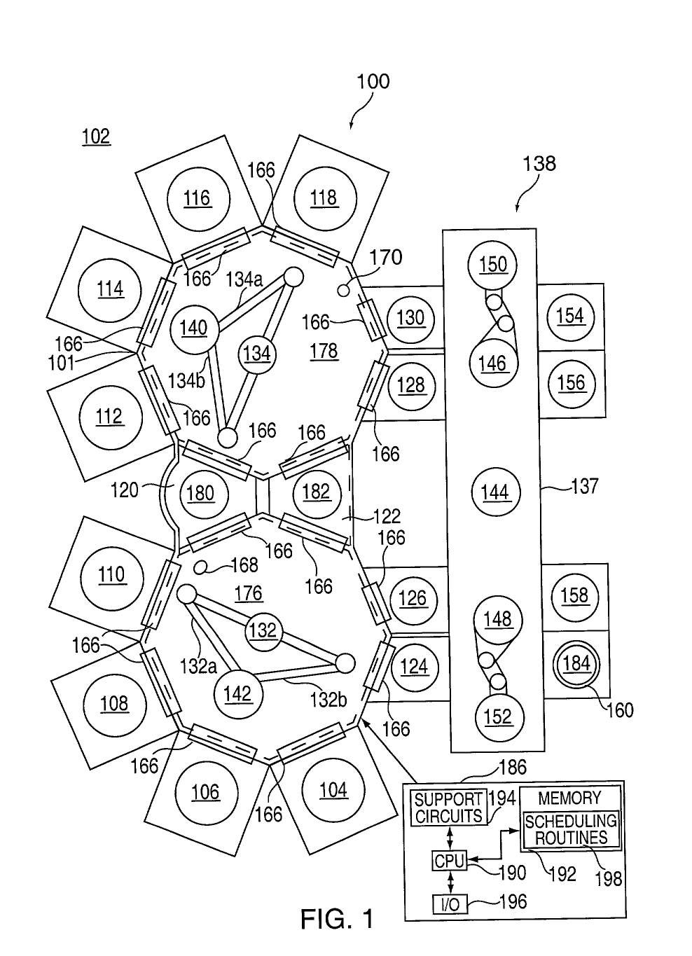

FIG. 1 depicts a schematic diagram of a dual buffer chamber, multiple process chamber, and semiconductor wafer processing system 102 (also referred to herein as a “cluster tool”) in accordance with the present invention. In this embodiment, increased wafer processing throughput is accomplished by increasing the number of load locks that are accessible to the buffer chambers 176 and 178 and implementing a dual loop process method for processing wafers.

The system 102 comprises a cluster tool 100 and a factory interface 138. The tool 100 comprises linked buffer chambers 176 and 178 housed in a polygonal platform 101, a plurality of process chambers 104-118 and four load lock chambers 124, 126, 128 and 130. While a configuration is shown having four load locks, configurations having any number of load locks, including six, eight or ten load locks are also contemplated by the invention.

Disposed about the perimeter of the polygonal platform 101, hereinafter referred to as the platform, are the process chambers 104-118. Process chambers 104-118 can be mounted at any one of at least eight facets provided on the platform 101. The load locks 124-130 transition wafers between atmospheric pressure within the factory interface 138 to a vacuum within the platform 101. A plurality of vacuum pumps (not shown) can be positioned below the cluster tool 100 in a “subfab” or basement. The process chambers 104-118 and the load locks 124-130 are oriented radially with respect to the center of the buffer chambers 176 and 178.

Each of the process and load lock chambers are selectively isolated from the buffer chambers 176 and 178 by a slit valve 166 creating a first and second environment, respectively, on either side of the valve. The use of slit valves 166 to isolate a process chamber from other chambers is known in the art and is described in U.S. Pat. No. 5,730,801 by Avi Tepman, et al., which is hereby incorporated by reference.

The dual linked polygonal structure of the platform 101 further comprises a pair of auxiliary chambers 120 and 122. The auxiliary chambers 120 and 122 provide passage between the buffer chambers 176 and 178. The auxiliary chambers 120 and 122 are also selectively isolated from adjoining buffer chambers 176 and 178 of the slit valves 166. Specifically, one slit valve 166 is provided between the first buffer chamber 176 and the first auxiliary chamber 120. An additional slit valve 166 is provided between the first auxiliary chamber 120 and the second buffer chamber 178, one slit valve is provided between the first buffer chamber 176 and second auxiliary chamber 122, another slit valve 166 is provided between the second buffer chamber 178 and second auxiliary chamber 122. The use of slit valves 166 allows for the pressure in each of the buffer chambers, 176 and 178, to be individually controlled. Each auxiliary chamber 120 and 122 additionally has a wafer pedestal 180 and 182, respectively, for supporting a wafer during the transfer process.

The auxiliary chambers 120 and 122 may comprise a simple pedestal that facilitates transfer of a wafer between buffer chambers (i.e., pass through); however, in the alternative, the chambers 120 and 122 may perform a process such as wafer cooling, wafer degas, wafer precleaning or wafer processing including material deposition or material removal.

FIG. 1 depicts two auxiliary chambers 120 and 122; however, the system 102 may operate using only a single auxiliary chamber. If one auxiliary chamber 122 is used, the polygonal platform 101 can be organized to add additional process chambers, e.g., a 10 process chamber platform as discussed with respect to FIG. 7 below.

The first buffer chamber 176 is in communication with load locks 124 and 126, as well as process chambers 104, 106, 108 and 110 and wafer transfer locations 120 and 122. Each of the process chambers 104, 106, 108 and 110 and the load locks 124 and 126 are selectively isolated from the buffer chamber 176 by slit valves 166. Within the buffer chamber 176 are a first vacuum port 168 and a first robot 132, e.g., a single blade robot (SBR). Other types of transport mechanisms may be substituted. The first robot 132 comprises a wafer transport blade 142 attached to the distal ends of a pair of extendable arms 133a and 133b. The blade 142 is used by the first robot 132 for carrying the individual wafers to and from the process chambers 104, 106, 108, and 110, transfer locations 120 and 122 and load locks 124 and 126 in communication with the first buffer chamber 176.

The second buffer chamber 178, similar to the first, is in communication with process chambers 112, 114, 116 and 118 as well as load locks 128 and 130 and wafer transfer locations 120 and 122. Located within the buffer chamber 178 is a second vacuum port 170 and a second robot 134, e.g., a single blade robot (SBR). Other types of robots may be substituted. The second robot 134 comprises a wafer transport blade 140 attached to the distal ends of a pair of extendable arms 134A and 134B. The blade 140 is used by the second robot 134 for carrying the individual wafers to and from the process chambers 112, 114, 116 and 118, transfer locations 120 and 122 and load locks 128 and 130 in communication with the second buffer chamber 178.

The vacuum ports 168 and 170 are connected to a pumping mechanism (not shown) such as a turbo molecular pump that is capable of evacuating the environments of chambers, respectively. The configuration and location of the vacuum ports 168 and 170 may vary, depending on design criteria for individual systems.

The system 102 comprises a factory interface (FI) 138. The FI 138 comprises a plurality of cassette loading stations 154, 156, 158 and 160 (also referred to herein as a wafer load/unload stage), one or more robots 146 and 148, one or more wafer orienter stations 150 and 152 and a wafer storage station 144. The robots 148 and 146 access cassette station 154, 156, 158 and 160 to move wafers 184, one at a time, from the cassettes to the load locks 124, 126, 128, 130 of the cluster tool 100. The robots 146 and 148 may move along a linear track assembly 137 to facilitate access to the load locks, orienters and other stations. Alternatively, the robots 146 and 148 may be stationery and designed to reach the various load locks and stations from fixed positions. Each wafer is typically oriented by an orienter 152 or 150 before being positioned in a load lock. The wafer storage station 144 is used to temporally place a wafer until a destination station or load lock is available. The storage station 144 may store one or more wafers.

The FI 138 may also comprise metrology, inspection or testing stations (not shown). When used, wafers are periodically removed from the tool 100 and positioned in a metrology, inspection or test station to facilitate defect control.

A sequencer 186 controls the processing and movement of wafers performed by the cluster tool 100. The sequencer 186 comprises a central processing unit (CPU) 190 as well as memory 192 for storing the scheduling routines, and support circuitry 194 such as power supplies, clock circuits, cache, and the like. The CPU 190 may be a microprocessor or microcontroller. The sequencer 186 also contains input/output circuitry 196 that forms an interface between conventional input/output (I/O) devices such as a keyboard, mouse, and display as well as an interface to the cluster tool. The sequencer 186 is a general-purpose computer that is programmed to perform the sequencing and scheduling operations that move wafers through the cluster tool 100 and the FI 138. The software routines 198 that implement the methods of the present invention are stored within memory 192 and executed by the CPU 190 to facilitate control of the robots within the cluster tool 100 and the FI 138.

In operation, the slit valves 166 isolating the buffer chambers 176 and 178 from the surrounding chambers remain closed unless the wafer transfer requires access to a particular chamber. The wafer processing, for example, begins with the buffer chambers 176 and 178 being pumped down to a vacuum by the pumping mechanism (not shown). The FI robot 148 moves a wafer 184 from the wafer load/unload stage 160 to an orienter 152 and then into a load lock 124. The first robotic wafer transport mechanism 132 retrieves a wafer 184 from the load lock 124 and carries the wafer 184 to a first stage of processing, for example, physical vapor deposition (PVD) in chamber 104. Once the robot 132 is no longer carrying a wafer, the robot 132 can service wafers in other chambers surrounding the buffer chamber 176. After the wafer is processed, the wafer can then be moved to a second stage of processing or any number of stages until the desired result is achieved.

Improved throughput occurs as a result of a dual loop process method being implemented in conjunction with the use of four load locks 124, 126, 128 and 130 that are accessible by two robots 132 and 134. Before the processing begins, wafers are moved through the factory interface 138 from the wafer load/unload stages 154, 156, 158 and 160 to populate the respective load locks.

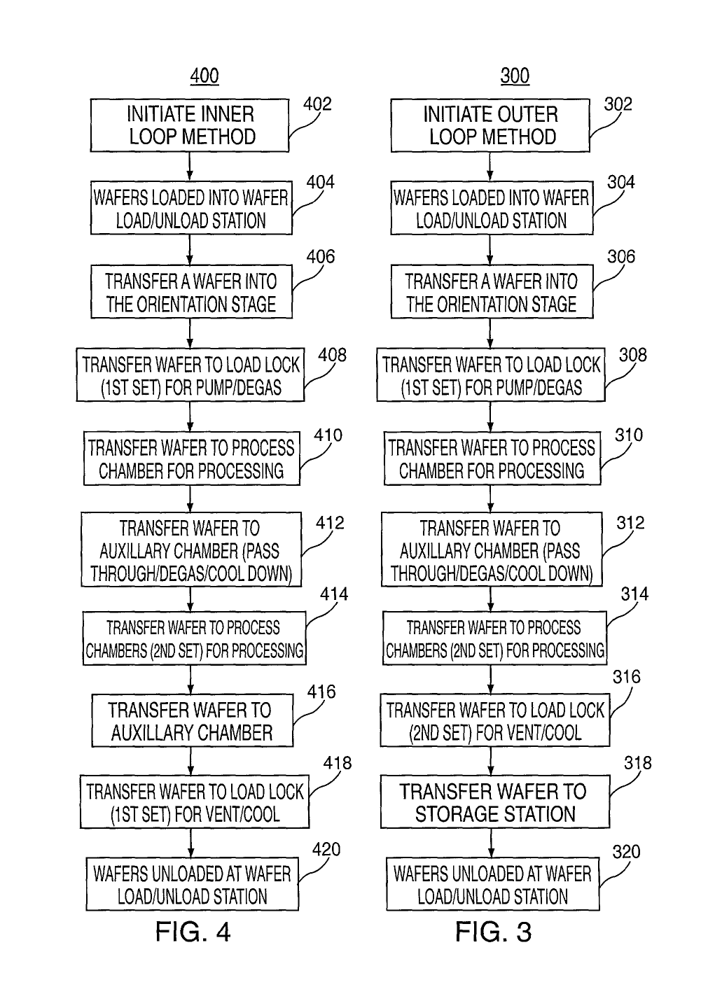

FIG. 3 depicts a flow diagram of an outer loop method 300 used in conjunction with the wafer-processing tool of FIG. 1 to process wafers consistent with the present invention. The outer loop method 300 is initiated at step 302 and proceeds to step 304 wherein wafers are loaded into a wafer load/unload stage. At step 306, a wafer is transferred into the orientator station. At step 308, the wafer is transferred to a load lock 124 to be degassed before being removed from the first load lock 124 by a robot 132. At step 310, the wafer is deposited in any one of a plurality of process chambers 104-110 that is designated by a process schedule. While a wafer is being processed, the robot may move other wafers either between process chambers, to/from the auxiliary chambers, or to/from the load locks. After the wafer has been processed by the chambers serviced by the first robot 132 of the first buffer chamber 176, the wafer, at step 312, is moved to an auxiliary chamber 120. The wafer auxiliary chambers 120 and 122 may be pass-through, de-gas, cooling chambers and the like. The wafer, at step 314, is then moved by the second robot 134. The second robot 134 may move the wafer into any one of a plurality of process chambers 112-118 associated with the second robot 134 for further processing. After processing the wafer, at step 316, the robot 134 moves the wafer to a second set of load locks 130 and 128 associated with the second robot 134. At step 318, the wafer may be moved from the load lock 130 into the storage station 144 as necessary. At step 320, the wafer may be moved to the same load/unload stage from either the load lock or the storage station.

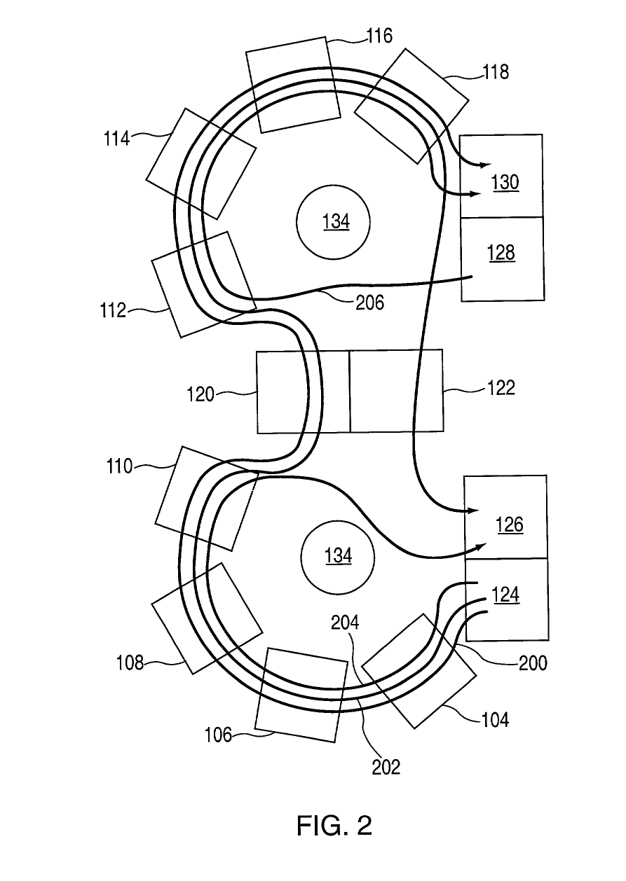

FIG. 2 depicts a block diagram of the cluster tool 100 of FIG. 1 illustrating various dual loop paths 200, 202, 204 and 206 that are performed by the various dual loop methods of the present invention. Although the paths 200, 202, 204 and 206 contact each process chamber, in practice, some of the process chambers may be skipped or repeated while a particular wafer is progressing through the cluster tool. Each path is intended to illustrate a general progression of a wafer through the tool 100.

The outer loop method 300 provides a path 200 from one set of load locks associated with a first robot (e.g., load locks 124 and 126 and robot 132) to a set of load locks associated with a second robot (e.g., load locks 128 and 130 and robot 134). As such, when using an outer loop method 300, the robot 132 may perform other tasks while the wafer exits the tool using robot 134. While a wafer is being processed, the robot may move other wafers either between process chambers, to/from the auxiliary chambers, or to/from the load locks. Consequently, throughput is increased over conventional cluster tools where the wafers enter and exit the tool using the same robot and set of load locks.

The path 202 produced by an inner loop process method 400 is illustrated in FIG. 2 and the series of steps of the method 400 are shown in FIG. 4. This method 400 is characterized by having wafers enter and exit a cluster tool from the same set of load locks.

During the inner loop process method 400, the process is initiated at step 402 and proceeds to step 404 wherein the wafer 184 within a wafer cassette is loaded into the wafer load/unload stage 160. In step 406, a wafer 184 is transferred into the orientator station 152. After orientation, the wafer 184 is transferred to a first set of load locks 124 in step 408 for vacuum pumping and degassing. After the load lock has been brought to the pressure of the cluster tool 102, in step 410, the wafer 184 is transferred by the robot 132 to one of the process chambers 104-110. In step 412, when processing is complete in chambers 104-110, the wafer 184 is transferred to one of the auxiliary chambers 120 or 122 that may serve a pass through, degas or cool down function. In step 414, the wafer 184 is transferred by the second robot 134 to any of the process chambers 112-118 associated with the second robot 134. Once processing is complete in chambers 112-118, the wafer 184 is transferred in step 416 to one of the auxiliary chambers 120 or 122 to be passed through to the first robot 132. In step 418, the first robot 132 moves the wafer 184 to the first set of load locks 126 to be vented and cooled. In step 420, the wafer 184 is moved from the load lock 126 to the same load/unload stage. While a wafer is being processed, the robot may move other wafers either between process chambers, to/from the auxiliary chambers, or to/from the load locks. The storage station 144 is used as necessary.

The inner loop method 400 can be combined with the outer loop method 300 to form a dual loop method. The dual loop method has wafers entering and exiting from both sets of load locks 124, 126, 128, 130. Such multiple exit and entry locations ensure that bottlenecks do not occur at the load locks. Consequently, throughput is increased over conventional cluster tools where the wafers enter and exit the tool using a single set of load locks and an associated robot.

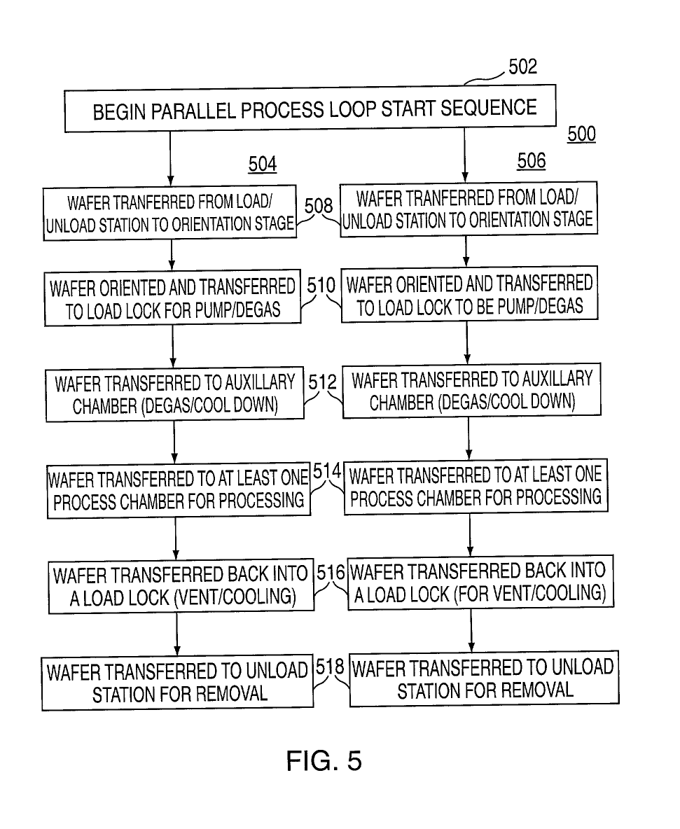

FIG. 5 depicts a flow diagram of a parallel loop method 500 used in conjunction with the wafer-processing tool of FIG. 1 to process wafers consistent with the present invention. The movement of wafers in accordance with the parallel loop process method 500 is represented by paths 204 and 206 of FIG. 2. Parallel processing occurs as each of the robots, their associated load locks and their associated environments act as complete individual wafer processing cluster tools. Each of the robots may execute the same tasks as its counterpart located in the adjacent environment. Alternatively, the two robots may operate independently and perform completely different processing on wafers. As in the previous process methods, all of the processes are controlled by sequencer 186 of FIG. 1 as previously discussed.

Following the steps of FIG. 5 it is noted that the same steps are followed along both process paths 504 and 506. Each process path 504 and 506 represents an individual series of steps to be performed by one of the robots 132, 134, 146 and 148 located in the tool 100. The parallel process loop 500 begins at step 502 where the robots and chambers are prepared to begin processing wafers. In step 508, a wafer 184 is transferred from a cassette in the load/unload stage to an orientator station. In step 510, the wafer is moved to a load lock in each set of load locks. After being vacuum pumped and degassed in the load locks, the wafers are then transferred to auxiliary chambers 120 and 122 in step 512 to be further degassed or cooled down. From the auxiliary chambers, the wafers 184 are transferred in step 514 to at least one process chamber each for processing. The wafers may be processed by a plurality of process chambers associated with each robot. After processing, in step 516, the wafers are transferred to their respective load locks where they are vented and cooled. Finally, in step 518, the wafers 184 are transferred to the wafer load/unload stages for removal.

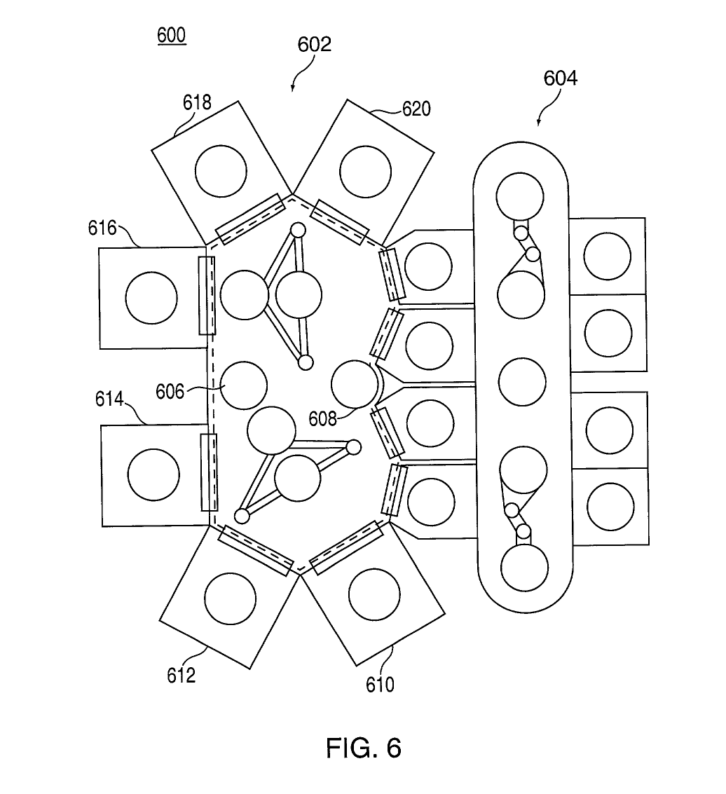

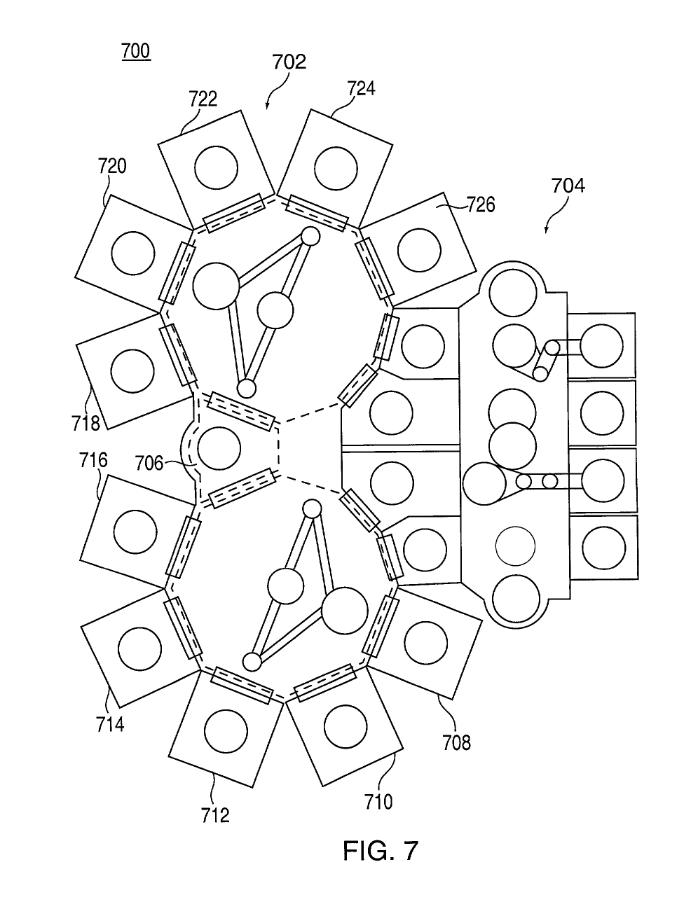

Further embodiments of the invention are depicted in FIGS. 6 and 7. FIG. 6 depicts a schematic view of a 6-chamber wafer processing system 600 comprising a 6-chamber cluster tool 602 and a factory interface 604. The factory interface is substantially similar to the factory interface 138 of FIG. 1. As such, no further description shall be presented.

The tool 602 operates in substantially the same manner as the tool 100 of FIG. 1. However, one difference between these two embodiments is that the tool 602 does not have auxiliary chambers (120 and 122 in FIG. 1), but rather has auxiliary pedestals 606 and 608 (also known as wafer transfer pedestals). The pedestals can be used to temporarily store wafers as the wafers are moved through the tool 602. As such, the wafer is positioned upon a pedestal to facilitate passing the wafer from one robot to another. Since a chamber does not surround the pedestals 606 and 608, the pedestal area is not used for processing the wafer. Although wafer cooling, lump degasing, and orientation could be accomplished by the pedestals.

The lack of auxiliary chambers and the use of only six process chambers 610-620 enable the tool 602 to have a smaller “footprint” than the embodiment of FIG. 1, i.e., tool 602 consumes less factory floor space than tool 100. The operation of the tool to implement inner, outer, dual and parallel process loops is substantially similar to the operation of the tool 100 in FIG. 1 described above with respect to FIGS. 2-5.

FIG. 7 depicts a schematic view of a 10-chamber wafer processing system 700 comprising a 10-chamber cluster tool 702 and a factory interface 704. The factory interface is substantially similar to the factory interface 138 of FIG. 1. As such, no further description shall be presented.

The tool 702 operates in substantially the same manner as the tool 100 of FIG. 1. However, one difference between these two embodiments is that the tool 702 does not have two auxiliary chambers (120 and 122 in FIG. 1), but rather has only one auxiliary chamber 706. The auxiliary chamber 706 operates in the same manner as chamber 120 and 122 described above. By using one auxiliary chamber, the tool can be expanded to comprise 10 process chambers 708-724.

The use of one less auxiliary chamber enables the use of ten process chambers 708-724 that results in higher throughput of processed wafers than available from the other embodiments of the invention. However, the ten chamber tool does consume additional factory floor space. The operation of the tool to implement inner, outer, dual and parallel process loops is substantially similar to the operation of the tool 100 in FIG. 1 described above with respect to FIGS. 2-5.

Various features of each of the foregoing embodiments can be combined to form other embodiments. For example, an 8-chamber cluster tool may use transfer pedestals in lieu of auxiliary chambers. Additionally, single auxiliary chamber could be used in either a 6- or 8-chamber tool. Any of the features of the embodiments shown in FIGS. 1-7 can be mixed and matched to derive other embodiments that are within the scope of the present invention.

Although various embodiments that incorporate the teachings of the present invention have been shown and described herein, those skilled in the art can readily devise many other varied embodiments that still incorporate these teachings.

What is claimed is:

1. An apparatus for processing semiconductor wafers comprising:
a first buffer chamber having a first robot;
a second buffer chamber having a second robot;
at least one load lock coupled to the first buffer chamber and the second buffer chamber, where the first and second robots can access at least one of said load locks; and
a plurality of process chambers disposed about said first and second buffer chambers.

2. The apparatus of claim 1, wherein said first and second robots can each access at least two load locks.

3. The apparatus of claim 1 further comprising a factory interface in communication with each of the load locks.

4. The apparatus of claim 1, wherein said at least one load lock is disposed between said first and second buffer chambers and a factory interface.

5. The apparatus of claim 1, wherein said first and second robots are in communication with each other.

6. The apparatus of claim 1, wherein said at least one load lock for each of the buffer chambers are disposed parallel and proximate to one another.

7. The apparatus of claim 1 wherein at least one auxiliary chamber is located between said first and second buffer chambers.

8. The apparatus of claim 7, wherein at least one of said auxiliary chambers is a passthrough, degas or process chamber.

9. An apparatus for processing semiconductor wafers comprising:
a first buffer chamber having a first robot;
a second buffer chamber having a second robot;
said first robot being associated with and in communication with a first set of process chambers and a first set of load locks;
said second robot being associated with and in communication with a second set of process chambers and second set of load locks; and
said first and second robots being in communication with each other.

10. The apparatus of claim 9, wherein said first and said second robots are in communication via at least one auxiliary chamber.

11. The apparatus of claim 10, wherein at least one of said auxiliary chambers is a passthrough, degas or process chamber.

12. A method of processing a wafer in a semiconductor wafer processing system comprising the steps of:
retrieving a wafer from a first load lock using a first robot that is located in a first buffer chamber;
moving the wafer using the first robot to a first process chamber;
processing said wafer in the first process chamber;
moving the wafer from the first process chamber using the first robot;
transferring said wafer to a second robot within a second buffer chamber;
moving the wafer using the second robot to a second process chamber;
processing the wafer in the second process chamber; and
moving the wafer from the second process chamber to a second load lock using the second robot.

13. The method of claim 12 further comprising the steps of:
retrieving a wafer from a first load lock using a first robot that is located in a first buffer chamber;
moving the wafer using the first robot to a first process chamber;
processing said wafer in the first process chamber; and
moving the wafer from the first process chamber to a third load lock using the first robot.

14. The method of claim 12, wherein the first and third load locks are the same load lock.

15. A method of processing a wafer in a semiconductor wafer processing system comprising the steps of:
retrieving a first wafer from a first load lock using a first robot that is located in a first buffer chamber while retrieving a second wafer from a second load lock using a second robot that is located in a second buffer chamber;
moving the first wafer using the first robot to a first process chamber while moving a second wafer using a second robot to a second process chamber;
processing each of said wafers in at least one process chamber;
moving the first wafer to the first load lock using the first robot; and
moving the second wafer to the second load lock using the second robot.
